(19) United States
(12) Patent Application Publication
(10) Pub. No.: US 2012/0211057 A1
(43) Pub. Date: Aug. 23, 2012

(54) PHOTOVOLTAIC BACK SHEET LAMINATES, PHOTOVOLTAIC MODULES COMPRISING PHOTOVOLTAIC BACK SHEET LAMINATES, AND METHODS FOR MAKING PHOTOVOLTAIC BACK SHEET LAMINATES

(75) Inventors: Yuan-Ping Robert Ting, Plainsboro, NJ (US); Simon J. Porter, Allentown, PA (US)

(73) Assignee: HONEYWELL INTERNATIONAL INC., Morristown, NJ (US)

(21) Appl. No.: 13/371,174

(22) Filed: Feb. 10, 2012

Related U.S. Application Data
(60) Provisional application No. 61/444,204, filed on Feb. 18, 2011.

(51) Int. Cl. H01L 31/048; B32B 37/14; H01L 31/0203

(52) U.S. Cl. 136/251; 136/259; 156/60

(57) ABSTRACT

Embodiments of photovoltaic back sheet laminates, photovoltaic modules containing photovoltaic back sheet laminates, and methods for making photovoltaic back sheet laminates are provided. The photovoltaic back sheet laminate comprises a first outer laminate section comprising an inner EVA layer, an outer EVA layer, and a pigmented core layer that is disposed between the inner and outer EVA layers. The pigmented core layer has a composition different than the inner and outer EVA layers. A second outer laminate section comprises a weatherable film. A mid-layer of polymer film is disposed between the first and second outer laminate sections.

### CROSS-REFERENCE TO RELATED APPLICATIONS

This application is related to and claims all available benefit of U.S. Provisional Patent Application 61/444,204 filed Feb. 18, 2011, the entire contents of which are herein incorporated by reference.

### FIELD OF THE INVENTION

The present invention relates generally to laminates, modules comprising laminates, and methods for making laminates, and more particularly relates to photovoltaic back sheet laminates, photovoltaic modules comprising photovoltaic back sheet laminates, and methods for making the photovoltaic back sheet laminates.

### BACKGROUND OF THE INVENTION

Photovoltaic (PV) modules are characterized by the efficiency with which they can convert incident solar power to useful electric power. PV modules utilizing crystalline silicon photovoltaic cells have achieved efficiencies of about 25% or greater. However, efficient crystalline-based PV cells are difficult and expensive to produce. To produce low-cost power, a solar cell needs to operate at high efficiency.

A number of techniques have been proposed for increasing the efficiency and effectiveness of PV modules. One approach is to enhance light reflection by a protective photovoltaic back sheet for the solar cell. The photovoltaic back sheet is typically formed as a laminate structure having several layers of polymeric materials including a reflective pigmented polymeric outer layer. The pigmented polymeric outer layer contains a significant amount of pigment to achieve a desired level of reflectivity. The photovoltaic cells of the PV module are disposed in a polymeric encapsulant that is bonded directly to the reflective pigmented polymeric outer layer. However, due to presence of the pigment in the reflective pigmented polymeric outer layer, robust bonding between the polymeric encapsulant and the reflective pigmented polymeric outer layer can be difficult to achieve.

Accordingly, it is desirable to provide a photovoltaic back sheet laminate that robustly bonds to the polymeric encapsulant of a photovoltaic module. Moreover, it is desirable to provide a method for making such a photovoltaic back sheet laminate. Furthermore, other desirable features and characteristics of the present invention will become apparent from the subsequent detailed description of the invention and the appended claims, taken in conjunction with the accompanying drawings and this background of the invention.

### SUMMARY OF THE INVENTION

Photovoltaic back sheet laminates, photovoltaic modules containing photovoltaic back sheet laminates, and methods for making photovoltaic back sheet laminates are provided herein. In accordance with an exemplary embodiment, a photovoltaic back sheet laminate comprises a first outer laminate section. The first outer laminate section comprises an inner EVA layer, an outer EVA layer, and a pigmented core layer that is disposed between the inner and outer EVA layers and has a composition different than the inner and outer EVA layers. A second outer laminate section comprises a weatherable film. A mid-layer of polymer film is disposed between the first and second outer laminate sections.

In accordance with another exemplary embodiment, a photovoltaic module comprises an EVA encapsulant. Photovoltaic cells are disposed in the EVA encapsulant. A photovoltaic back sheet laminate comprises a first outer laminate section. The first outer laminate section comprises an inner EVA layer, an outer EVA layer, and a pigmented core layer that is disposed between the inner and outer EVA layers and has a composition different than the inner and outer EVA layers. The outer EVA layer is bonded to the EVA encapsulant. A second outer laminate section comprises a weatherable film. A mid-layer of polymer film is disposed between the first and second outer laminate sections.

In accordance with another exemplary embodiment, a method for making a photovoltaic back sheet laminate comprises the steps of forming a first outer laminate section. The first outer laminate section comprises an inner EVA layer, an outer EVA layer, and a pigmented core layer that is disposed between the inner and outer EVA layers and has a composition different than the inner and outer EVA layers. A mid-layer of polymer film is laminated to the inner EVA layer. A second outer laminate section comprising a weatherable film is laminated to the mid-layer.

### BRIEF DESCRIPTION OF THE DRAWINGS

Embodiments of the present invention will hereinafter be described in conjunction with the following drawing figures, wherein like numerals denote like elements, and wherein:

FIG. 1 is an exploded perspective view of a photovoltaic module in accordance with an exemplary embodiment; and

FIG. 2 is a cross-sectional view of a photovoltaic back sheet laminate in accordance with an exemplary embodiment.

### DETAILED DESCRIPTION

The following Detailed Description is merely exemplary in nature and is not intended to limit the invention or the application and uses of the invention. Furthermore, there is no intention to be bound by any theory presented in the preceding Background of the Invention or the following Detailed Description.

The various embodiments contemplated herein relate to photovoltaic back sheet laminates, photovoltaic modules containing photovoltaic back sheet laminates, and methods for making the photovoltaic back sheet laminates. The various embodiments comprise a photovoltaic back sheet laminate for incorporation into a photovoltaic module that includes photovoltaic cells disposed in a polymeric encapsulant comprising ethylene vinyl acetate copolymer (hereinafter “EVA”). The photovoltaic back sheet laminate comprises a first outer laminate section, a second outer laminate section that comprises a weatherable film, and a mid-layer of polymer film that is disposed between the first and second outer laminate sections. The first outer laminate section comprises an inner EVA layer, an outer EVA layer, and a pigmented core layer that is disposed between the inner and outer EVA layers. In an exemplary embodiment, the pigmented core layer comprises polyethylene and pigment. The pigment is an opacifying pigment that effectively increases the optical density and reflectivity of the pigmented core layer. In an exemplary embodiment, the inner and outer EVA layers comprise ethylene vinyl acetate copolymer and polyethylene and substantially no pigment. The term “substantially no pigment” as used herein means the pigment, if present is used in an amount that does not measurably increases the optical density and reflectivity of the EVA layers. Preferably, the first outer laminate section is formed as a multilayer film by a coextrusion process or other suitable process that melt-fusion bonds the pigmented core layer with the inner and outer EVA layers. Because the inner and outer EVA layers contain substantially no pigment, the outer EVA layer readily bonds with the EVA encapsulant. In an exemplary embodiment, the outer EVA layer has improved melt flow properties due to the lack of pigment and robustly bonds to the EVA encapsulant by a heat seal bonding process and/or a lamination process and the like.

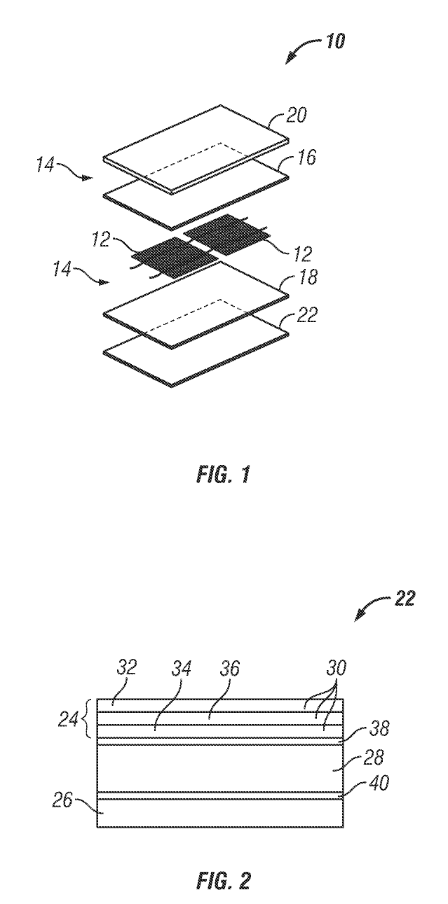

Referring to FIG. 1, an exploded perspective view of an exemplary embodiment of a photovoltaic module 10 is provided. The photovoltaic module 10 comprises photovoltaic cells 12 that are spaced apart from each other and are configured to convert incident light, e.g., incident solar light, to electrical power that may be sent, for example, to a battery or, with an inverter, to a power grid. The photovoltaic cells 12 may be crystalline silicon solar cells or any other type of solar cells known to those skilled in the art. The photovoltaic cells 12 are disposed in an EVA encapsulant 14 that is formed by an upper EVA encapsulant sheet 16 and a lower EVA encapsulant sheet 18. The upper and lower EVA encapsulant sheets 16 and 18 are brought together, e.g., via a lamination process or the like, to encapsulate the photovoltaic cells 12 between the sheets 16 and 18.

A glass front 20 is positioned over the upper EVA encapsulant sheet 16 and provides protection to the EVA encapsulant 14 from exposure to environmental conditions. The glass front 20 and the EVA encapsulant 14 are preferably substantially transparent to allow incident light to reach the photovoltaic cells 12 for conversion to electrical power.

Adjacent to the lower EVA encapsulant sheet 18 is a photovoltaic back sheet laminate 22. The photovoltaic back sheet laminate 22 is used as a barrier for protecting the EVA encapsulant 14 and is configured to reflect incident light passing between the photovoltaic cells 12 back towards the photovoltaic cells 12 for conversion to electrical power. The photovoltaic back sheet laminate 22 is preferably resistant to break down effects associated with exposure to environmental conditions, including UV and other bands of sunlight, heat, moisture and electrical forces. In an exemplary embodiment, the photovoltaic back sheet laminate 22 is bonded to the EVA encapsulant 14, such as, for example, via a heat seal bonding process or a lamination process including roll lamination, vacuum lamination, and the like.

Referring to FIG. 2, a cross-sectional view of the photovoltaic back sheet laminate 22 depicted in FIG. 1 is provided. As illustrated, the photovoltaic back sheet laminate 22 comprises a first outer laminate section 24, a second outer laminate section 26 and a mid-layer of polymer film 28 that is disposed between the first and second outer laminate sections 24 and 26.

The first outer laminate section 24 is preferably formed as a multilayer film 30 and comprises at least three layers including an outer EVA layer 32, an inner EVA layer 34 and a pigmented core layer 36 that is disposed between the outer and inner EVA layers 32 and 34. The outer EVA layer 32 is for directly bonding the photovoltaic back sheet laminate 22 to the EVA encapsulant 14, the pigmented core layer 36 is configured for reflecting incident light back towards the photovoltaic cells 12, and the inner EVA layer 34 is for directly bonding the first outer laminate section 24 to the remaining portion of the photovoltaic back sheet laminate 22. In the exemplary embodiments where the first outer laminate section 24 comprises more than three layers, the additional layers are positioned between the outer EVA layer 32 and the pigmented core layer 36 and/or the pigmented core layer 36 and the inner EVA layer 34.

The thickness of the first outer laminate section 24 is preferably of from about 50 to about 200 microns (μm), more preferably of from about 75 to about 125 μm, and most preferably of about 100 μm. The thickness of the pigmented core layer 36 is about 20% to about 80% of the total thickness of the multilayer film 30. In one example, the outer and inner EVA layers 32 and 34 each have a thickness of about 25 μm, and the pigmented core layer 36 has a thickness of about 50 μm.

The outer and inner EVA layers 32 and 34 may have the same, substantially similar, or distinctly different compositions, but both of the EVA layers 32 and 34 comprise ethylene vinyl acetate copolymer, and preferably further comprise polyethylene. In an exemplary embodiment, the outer and inner EVA layers 32 and 34 comprise substantially no opacifying pigment that effectively increases the optical density and reflectivity of the layers 32 and 34. Preferably, the outer and inner EVA layers 32 and 34 have a vinyl acetate content of from about 2 to about 20 weight percent (wt. %), and more preferably of from about 2 to about 10 wt. %, and most preferably of from about 3 to about 4 wt. %, of the outer and inner EVA layers 32 and 34, respectively. The outer and inner EVA layers 32 and 34 preferably comprise ethylene vinyl acetate copolymer that is present in an amount of from about 19 to about 30 wt. % of the outer and inner EVA layers 32 and 34, respectively. In the exemplary embodiments where the outer and/or inner EVA layers 32 and 34 further comprise polyethylene, the polyethylene is present in an amount of from about 70 to about 81 wt. % of the outer and/or inner EVA layers, respectively. The preferred polyethylene includes linear low-density polyethylene, low-density polyethylene, or mixtures thereof.

In an exemplary embodiment, the outer EVA layer 32 is substantially transparent to incident light and the pigmented core layer 36 has a reflectivity of at least about 75% for reflecting the incident light back towards the photovoltaic cells 12. The pigmented core layer 36 has a composition different from both the outer and inner EVA layers 32 and 34 and comprises polyethylene and pigment. The polyethylene is preferably present in an amount of from about 80 to about 95 wt. % of the pigmented core layer 36. Examples of the preferred polyethylene include linear low-density polyethylene, low-density polyethylene, or mixtures thereof. The pigment may be any opacifying pigment that effectively increases the optical density and reflectivity of the pigmented core layer 36. The pigment is preferably present in an amount of from about 5 to about 20 wt. %, more preferably of from about 10 to about 14 wt. %, and most preferably about 12 wt. % of the pigmented core layer 36. The preferred pigments include titanium dioxide, zinc oxide, carbon black, barium sulfate, or mixtures thereof, the more preferred include white opacifying pigment, such as, titanium dioxide, zinc oxide, barium sulfate, or mixtures thereof, and the most preferred include titanium dioxide, zinc oxide, or mixtures thereof. In a preferred embodiment, the pigmented core layer 36 contains substantially no ethylene vinyl acetate copolymer (EVA). The term “substantially no ethylene vinyl acetate copolymer” as used herein means the EVA, if present is in the pigmented core layer 36 only along the bonded interfaces with the outer and inner EVA layers 32 and 34.

The first outer laminate section 24 is formed preferably by a coextrusion process. However, other processes known to those skilled in the art may be used that melt-fusion bond multiple polymeric layers together. In one example, the first outer laminate section 24 is formed by using a flow plate in a coextrusion polyethylene blow line as is known in the art to form a blown film. The blown film comprises the outer and inner EVA layers 32 and 34 and the pigmented core layer 36. The blown film may be surface treated (e.g. corona, plasma and the like) on the inner EVA layer 34 side for subsequent bonding to the mid-layer of polymer film 28. In an exemplary embodiment, the outer EVA layer 32 is formed with a small amount (e.g. less than about 1 wt. %) of peroxide initiator. The outer EVA layer 32 containing the peroxide initiator may reduce the overall lamination time for bonding the outer EVA layer 32 to the EVA encapsulant 14 during a lamination process or the like to improve the overall manufacturing time for forming the photovoltaic module 10. For example, the time for the final lamination step for bonding the outer EVA layer 32 to the EVA encapsulant 14 may be typically about 15 minutes at a temperature of about 150° C. However, with the peroxide initiator in the outer EVA layer 32, a robust bond between the outer EVA layer 32 and the EVA encapsulant 14 may be formed more quickly and further, the EVA encapsulant 14 may be cured more rapidly so that the time for the final lamination step may be, for example, from about 7 to about 12 minutes at a temperature of 150° C.

The weatherable film of the second outer layer 26 is a dielectric film that preferably contains an opacifying pigment for optical density and reflectivity, and that can withstand exposure to environmental conditions, including UV and other bands of sunlight, heat, moisture and electrical forces. The thickness of the second outer layer 26 is preferably of from about 25 to about 200 μm, and more preferably of from about 50 to about 125 μm.

In an exemplary embodiment, the weatherable film comprises a fluoropolymer and pigment. Preferably, the fluoropolymer and pigment are present in amounts of about 70 to about 97 wt. % and from about 3 to about 30 wt. % of the second outer layer 26, respectively. Non-limiting examples of preferred fluoropolymers include chlorotrifluoroethylene-vinylidene fluoride copolymer (CTFE/VDF), ethylene-chlorotrifluoroethylene copolymer (ECTFE), ethylene-tetrafluoroethylene copolymer (ETFE), fluorinated ethylene-propylene copolymer (FEP), polychlorotrifluoroethylene (PCTFE), perfluoroalkyl-tetrafluoroethylene copolymer (PFA), polytetrafluoroethylene (PTFE), polyvinylidene fluoride (PVDF), tetrafluoroethylene-hexafluoropropylene copolymer (TFE/HFP), hexafluoropropylene-vinylidene fluoride copolymer (HFP/VDF), tetrafluoroethylene-propylene copolymer (TFE/P), tetrafluoroethylene-perfluoromethylether copolymer (TFE/PFMe), perfluorinated polyethers, or mixtures thereof, and most preferred is ECTFE. Non-limiting examples of the preferred pigment include titanium dioxide, zinc oxide, carbon black, barium sulfate, or mixtures thereof, the more preferred include white opacifying pigment, such as, titanium dioxide, zinc oxide, barium sulfate, or mixtures thereof, and the most preferred include titanium dioxide, zinc oxide, or mixtures thereof.

The mid-layer of polymer film 28 provides stiffness and strength to the photovoltaic back sheet laminate 22. In an exemplary embodiment, the mid-layer of polymer film 28 is a polyester film, such as, for example, a polyethylene terephthalate (PET) film, polybutylene terephthalate (PBT) film, or polyethylene naphthalate (PEN) film. The thickness of the mid-layer of polymer film 28 is preferably of from about 50 to about 250 μm, and more preferably of from about 100 to about 150 μm.

In an exemplary embodiment, the first and second outer laminate sections 24 and 26 are bonded to the mid-layer of polymer film 28 by a first adhesive layer 38 and a second adhesive layer 40, respectively. The first and second adhesive layers 38 and 40 may be formed of the same type of adhesive or different types of adhesives. The first and second adhesive layers 30 and 40 may be formed from a thermoplastic adhesive, a chain extending thermal cure adhesive, and/or a thermoset adhesive. Non-limiting examples of adhesives for forming the first and second adhesive layers include acrylic adhesive, poly(methyl methacrylate) adhesive, cyanoacrylate adhesive, epoxy adhesive, polyurethane adhesive, silicones adhesive, phenolic adhesive, polyimide adhesive, and mixtures thereof, and most preferably a two-part chain extending thermal cure polyurethane adhesive.

In an exemplary embodiment, the adhesive layers 38 and 40 are formed including coating the corresponding surfaces of the inner EVA layer 34 and/or the mid-layer of polymer film 28, and the corresponding surfaces of the mid-layer of polymer film 28 and/or the second outer laminate section 26 prior to contacting the respective surfaces together. The adhesive may be coated onto the corresponding surfaces by any conventional means, such as, for example, spray, roll, knife, curtain, gravure coaters, or any method that permits the application of a uniform coating without streaks or other defects. After applying the adhesive to the corresponding surfaces, the coated adhesive is dried, e.g., at a temperature of from about 50 to about 80° C., to form the corresponding adhesive layers 38 and 40 in an unreacted condition. The first outer laminate section 24, the mid-layer of polymer film 28, the second outer laminate section 26, and the adhesive layers 38 and 40 are positioned as a stack, as illustrated in FIG. 2, and fed into a laminating nip as is known in the art. The laminating nip presses the stack together at a temperature of from about 120 to about 175° C., curing the adhesive and forming the photovoltaic back sheet laminate 22.

The following is an example of a compositional formulation for a 3 layer multilayer film outer laminate section in accordance with an exemplary embodiment with each of the components set forth in weight percent. The example is provided for illustration purposes only and is not meant to limit the various embodiments of the multilayer film outer laminate section in any way.

### EXAMPLE

### Compositional Formulation for a 3 Layer Multilayer Film

Outer EVA Layer:

| Outer EVA Layer - Ingredient | Wt. % |
|---|---|
| LLDPE | 45-56 |
| LDPE | 20-30 |
| EVA with a vinyl acetate content of about 14% | 12-18 |
| Total | 100.0 |

Inner EVA Layer:

| Outer EVA Layer - Ingredient | Wt. % |
|---|---|
| LLDPE | 45-56 |
| LDPE | 20-30 |
| EVA with a vinyl acetate content of about 14% | 12-18 |
| Total | 100.0 |

Pigmented Master Batch and Pigmented Core Layer:

| | Wt. % |
|---|---|
| White Pigmented Master Batch - Ingredient | |
| LLDPE | 50-70 |
| Titanium Dioxide | 30-50 |
| Heat Stabilizer | 0.1-0.3 |
| Antioxidant | 0.1-0.3 |
| Total | 100.0 |
| Pigmented Core Layer - Ingredient | |
| LLDPE | 40-50 |
| LDPE | 20-30 |
| White Pigmented Master Batch | 25-35 |
| Total | 100.0 |

Accordingly, photovoltaic back sheet laminates, photovoltaic modules including photovoltaic back sheet laminates, and methods for making the photovoltaic back sheet laminates have been described. The various embodiments comprise a photovoltaic back sheet laminate for incorporation into a photovoltaic module that includes photovoltaic cells dispose in an EVA encapsulant. The photovoltaic back sheet laminate comprises a first outer laminate section, a second outer laminate section that comprises a weatherable film, and a mid-layer of polymer film that is disposed between the first and second outer laminate sections. The first outer laminate section comprises an inner EVA layer, an outer EVA layer and a pigmented core layer that is disposed between the inner and outer EVA layers. In an exemplary embodiment, the pigmented core layer comprises polyethylene and pigment. The pigment is an opacifying pigment that effectively increases the optical density and reflectivity of the pigmented core layer. In an exemplary embodiment, the inner and outer EVA layers comprise ethylene vinyl acetate copolymer and polyethylene and substantially no pigment. Because the inner and outer EVA layers contain substantially no pigment, the outer EVA layer readily bonds with the EVA encapsulant. In an exemplary embodiment, the outer EVA layer is robustly bonded to the EVA encapsulant by a heat seal bonding process and/or a lamination process and the like, and the inner EVA layer is robustly bonded to the mid-layer of polymer film by an adhesive layer.

While at least one exemplary embodiment has been presented in the foregoing Detailed Description, it should be appreciated that a vast number of variations exist. It should also be appreciated that the exemplary embodiment or exemplary embodiments are only examples, and are not intended to limit the scope, applicability, or configuration of the invention in any way. Rather, the foregoing Detailed Description will provide those skilled in the art with a convenient road map for implementing an exemplary embodiment of the invention, it being understood that various changes may be made in the function and arrangement of elements described in an exemplary embodiment without departing from the scope of the invention as set forth in the appended Claims and their legal equivalents.

What is claimed is:

1. A photovoltaic back sheet laminate comprising:
a first outer laminate section comprising an inner EVA layer, an outer EVA layer and a pigmented core layer that is disposed between the inner and outer EVA layers and has a composition different than the inner and outer EVA layers;
a second outer laminate section comprising a weatherable film; and
a mid-layer of polymer film disposed between the first and second outer laminate sections.

2. The photovoltaic back sheet laminate according to claim 1, wherein the inner and outer EVA layers comprise ethylene vinyl acetate copolymer and polyethylene.

3. The photovoltaic back sheet laminate according to claim 2, wherein the inner and outer EVA layers have a vinyl acetate content of from about 2 to about 20 wt. % of the inner and outer EVA layers, respectively.

4. The photovoltaic back sheet laminate according to claim 2, wherein the inner and outer EVA layers comprise ethylene vinyl acetate copolymer present in an amount of from about 19 to about 30 wt. % of the inner and outer EVA layers, respectively.

5. The photovoltaic back sheet laminate according to claim 2, wherein the inner and outer EVA layers comprise polyethylene present in an amount of from about 70 to about 81 wt. % of the inner and outer EVA layers, respectively.

6. The photovoltaic back sheet laminate according to claim 2, wherein the polyethylene is selected from the group consisting of linear low-density polyethylene, low-density polyethylene, and mixtures thereof.

7. The photovoltaic back sheet laminate according to claim 1, wherein the inner and outer EVA layers contain substantially no pigment.

8. The photovoltaic back sheet laminate according to claim 1, wherein the pigmented core layer comprises pigment selected from the group consisting of titanium dioxide, zinc oxide, carbon black, barium sulfate, carbon black, and mixtures thereof.

9. The photovoltaic back sheet laminate according to claim 8, wherein the pigmented core layer further comprises polyethylene.

10. The photovoltaic back sheet laminate according to claim 8, wherein the pigmented core layer comprises the pigment present in an amount of about 5 to about 20 wt. % of the pigmented core layer.

11. The photovoltaic back sheet laminate according to claim 1, wherein the weatherable film comprises a fluoropolymer and pigment.

12. The photovoltaic back sheet laminate according to claim 1, wherein the polymeric film of the mid-layer comprises polyester.

13. The photovoltaic back sheet laminate according to claim 1, further comprising a first adhesive layer and a second adhesive layer, wherein the first adhesive layer bonds the inner EVA layer to the mid-layer, and the second adhesive layer bonds the mid-layer to the second outer laminate section.

14. The photovoltaic back sheet laminate according to claim 1, wherein the inner and outer EVA layers each have a thickness of about 25 μm, and the pigmented core layer has a thickness of about 50 μm.

15. The photovoltaic back sheet laminate according to claim 1, wherein the outer EVA layer comprises a peroxide initiator.

16. A photovoltaic module comprising:
an EVA encapsulant;
photovoltaic cells disposed in the EVA encapsulant; and
a photovoltaic back sheet laminate comprising:
a first outer laminate section comprising an inner EVA layer, an outer EVA layer and a pigmented core layer that is disposed between the inner and outer EVA layers and has a composition different than the inner and outer EVA layers, and wherein the outer EVA layer is bonded to the EVA encapsulant;
a second outer laminate section comprising a weatherable film; and
a mid-layer of polymer film disposed between the first and second outer laminate sections.

17. A method for making a photovoltaic back sheet laminate comprising the steps of:
forming a first outer laminate section comprising an inner EVA layer, an outer EVA layer and a pigmented core layer that is disposed between the inner and outer EVA layers and has a composition different than the inner and outer EVA layers;
laminating a mid-layer of polymer film to the inner EVA layer; and
laminating a second outer laminate section comprising a weatherable film to the mid-layer of polymer film.

18. The method according to claim 17, wherein the step of forming includes forming the inner and outer EVA layers comprising ethylene vinyl acetate copolymer and polyethylene.

19. The method according to claim 18, wherein the step of forming includes forming the inner and outer EVA layers having a vinyl acetate content of from about 2 to about 20 wt. % of the inner and outer EVA layers, respectively.

20. The method according to claim 17, wherein the step of forming includes forming the pigmented core layer comprising pigment, and forming the inner and outer EVA layers containing substantially no pigment.
